(19) United States
(12) Patent Application Publication
(10) Pub. No.: US 2016/0198574 A1
(43) Pub. Date: Jul. 7, 2016

(54) SUBSTRATE WITH ELECTRONIC DEVICE EMBEDDED THEREIN AND MANUFACTURING METHOD THEREOF

(71) Applicant: Samsung Electro-Mechanics Co., Ltd., Suwon-si (KR)

(72) Inventors: Nam-Gil LEE, Daejeon (KR); Cheol-Ho CHOI, Hwaseong-si (KR)

(73) Assignee: Samsung Electro-Mechanics Co., Ltd., Suwon-si (KR)

(21) Appl. No.: 14/984,043

(22) Filed: Dec. 30, 2015

(30) Foreign Application Priority Data
Jan. 5, 2015 (KR) 10-2015-0000673

(51) Int. Cl. H05K 1/18; H05K 3/32; H05K 3/00; H05K 3/46; H05K 1/03; H05K 1/02

(52) U.S. Cl. CPC H05K 1/185; H05K 1/0373; H05K 1/0298; H05K 3/0011; H05K 3/4697; H05K 3/32; H05K 2201/0358; H05K 2201/0154

(57) ABSTRACT

An electronic device embedded substrate and a method of manufacturing the same are disclosed. The electronic device embedded substrate includes a core substrate comprising a polyimide resin layer disposed on one side of a cavity of the core substrate, an electronic device embedded in the cavity, and an insulation layer disposed on both surfaces of the core substrate so as to cover the core substrate and the electronic device.

### CROSS-REFERENCE TO RELATED APPLICATIONS

This application claims the benefit under 35 USC 119(a) of Korean Patent Application No. 10-2015-0000673, filed on Jan. 5, 2015, in the Korean Intellectual Property Office, the entire disclosure of which is incorporated herein by reference for all purposes.

### BACKGROUND

1. Field

The following description relates to an electronic device embedded substrate and a manufacturing method thereof.

2. Description of Related Art

In the electronics manufacturing industry, active elements and passive elements are often mounted on the top of a substrate by using surface mount technology (SMT). However, electronic products have been increasingly getting smaller, and new packing technologies have been developed to embed the active and passive elements in the substrate.

In the case of active/passive element-embedded substrate products, economical manufacturing processes are possible by integrating various active/passive elements in organic substrates, and the module products utilizing this packaging technology can contribute to making the products smaller.

Moreover, in addition to the ability to integrate components and to produce compact products, the active/passive element-embedded substrate encompasses a highly functional aspect, thanks to providing a solution for possible reliability issues occurred during electrical connection of elements in a flip chip or a ball grid array by use of wire bonding or solder ball. An example of a substrate with an electronic element embedded therein is provided in Korea Patent Publication No. 10-2010-0059010 (laid open on Jun. 4, 2010).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device embedded substrate includes a core substrate including a polyimide resin layer disposed on one side of a cavity of the core substrate, an electronic device embedded in the cavity, and an insulation layer disposed on both surfaces of the core substrate so as to cover the core substrate and the electronic device.

A thickness of the polyimide resin layer may be smaller than a thickness of the electronic device.

The thickness of the polyimide resin layer may range between approximately 0.5 to 10 μm.

The polyimide resin layer may include a resin impregnated with a filler.

An outer layer circuit pattern may be disposed on or within the insulation layer, and the outer layer circuit pattern may be electrically connected with the electronic device.

An inner layer circuit pattern may be formed on a surface of the core substrate.

In another general aspect, a method of manufacturing an electronic device embedded substrate involves forming a cavity in a core substrate, forming a polyimide resin layer and an insulation layer on one surface of the core substrate so as to cover one side of the cavity, embedding an electronic device in the cavity by supporting the electronic device with the polyimide resin layer, and forming an insulation layer on another surface of the core substrate so as to cover the core substrate and the electronic device.

The forming of the insulation layer may involve compressing a prepreg (PPG) and a copper foil laminated on both surfaces of the core substrate.

In another general aspect, a method of manufacturing an electronic device embedded substrate involves disposing an electronic device in a cavity of a core substrate by using a polyimide resin layer, and embedding the electronic device in the cavity by forming an insulation layer to cover the cavity and the electronic device.

The embedding of the electronic device may involve forming an insulation layer to cover the electronic device while the electronic device is disposed in the cavity of the core substrate by being supported on the polyimide resin layer.

The general aspect of the method may further involve forming an outer layer circuit pattern on or within the insulation layer by forming a via in the insulating layer and filling the via with a conductor such that the outer layer circuit pattern is electrically connected with the electronic device.

Other features and aspects will be apparent from the following detailed description, the drawings, and the claims.

### BRIEF DESCRIPTION OF THE DRAWINGS

FIG. 1 is a diagram illustrating an example of an electronic device embedded substrate.

FIG. 2 is a flow diagram illustrating an example of a method of manufacturing an electronic device embedded substrate.

FIG. 3, FIG. 4, FIG. 5, FIG. 6 and FIG. 7 are diagrams illustrating steps of an example of a method of manufacturing an electronic device embedded substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless clearly used otherwise, expressions in a singular form include a meaning of a plural form.

In the present description, when any part is described to “comprise” or “include” any element, it is intended to describe the possibility of encompassing additional element(s), rather than excluding any other element, unless otherwise described. Moreover, when any element is described to be “on,” “above” or “over” any part or element, it shall be understood that such element is placed above or below such part or element and not necessarily at a gravitationally higher position.

When one element is described to be “coupled” to another element, it does not refer to a physical, direct contact between these elements only, but it shall also include the possibility of yet another element being interposed between these elements and each of these elements being in contact with said yet another element.

Terms such as “first” and “second” may be used for describing various elements, but the above elements shall not be restricted to the above terms. The above terms may be used for merely distinguishing one element from other identical or corresponding elements.

The size and thickness of each element shown in the drawings are provided for the convenience of description, illustration and understanding, and thus the present description shall not be limited to how the drawings are illustrated.

Hereinafter, an electronic device embedded substrate and a method of manufacturing the same in accordance with certain embodiments of the present description will be described in detail with reference to the accompanying drawings. In describing the present description with reference to the accompanying drawings, any identical or corresponding elements will be assigned with same reference numerals, and no redundant description thereof will be provided.

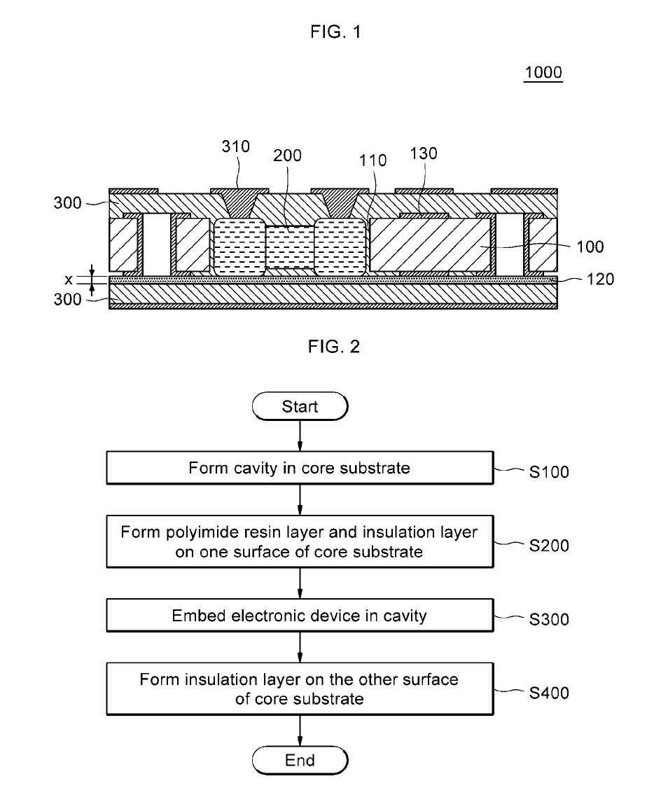

FIG. 1 illustrates an example of a substrate in which an electronic device is embedded.

Referring to FIG. 1, an electronic device embedded substrate 1000 includes a core substrate 100, an electronic device 200 and an insulation layer 300.

The core substrate 100 may be a laminate such as a copper clad laminate (CCL) constituted with resin layer and a copper film, for example. The core substrate 100 may have a specific circuit pattern formed thereon. Referring to FIG. 1, the core substrate 100 includes a polyimide resin layer 120 formed on one side of a cavity 110.

The cavity 110 refers to a space for embedding an electronic device 200 in the core substrate 100. The cavity 110 can be formed by a punching method using a CNC drill or a metallic mold or a drilling method using laser, such as a CO₂ laser or Nd:YAG laser.

The polyimide resin layer 120 is a synthetic polymer layer having imide coupling. The polyimide resin layer 120 may be used as an insulation material, owing to its excellent heat-resisting and insulating properties. The polyimide resin layer 120 has adhesiveness in a resin state and thus may have the electronic device 200 adhered thereto. When hardened, the polyimide resin layer 120 may support the electronic device 200 in the cavity 110.

As the polyimide resin layer 120 itself may be used as an insulation material, the polyimide resin layer 120 does not have to be removed after the electronic device 200 is embedded. The polyimide resin layer 120 also has a relatively smaller coefficient of thermal expansion than epoxy, which is also usable as an insulation material; thus, in comparison to an insulation layer formed with epoxy, the polyimide resin layer 120 may provide a more stable and sturdy insulation layer.

The electronic device 200 that is embedded in the cavity 110 while being supported by the polyimide resin layer 120 within the substrate, may be an active element such as an IC chip or a passive element such as a capacitor, an inductor or the like.

In order to embed the electronic device 200 in the cavity 110, the electronic device 200 may need to be stabilized by use of, for example, a heat-resistant tape. However, as the heat-resistant tape or the like has to be removed during the manufacturing process, introduction of the heat-resistant tape or the like may complicate the manufacturing process.

Moreover, any residue of the heat-resistant tape or the like that is not completely removed may cause interlayer exfoliation, possibly resulting in a deteriorated reliability of the electronic device embedded substrate 1000.

In accordance with the present example, the polyimide resin layer 120 as described above may be used to support the electronic device to be embedded in the substrate 1000 without using any heat-resistant tape or the like.

The insulation layer 300 is formed on both surfaces of the core substrate 100 so as to cover the core substrate 100 and the electronic device 200, forming an insulation coated structure for protecting the core substrate 100 and the electronic device 200.

As described above, the electronic device embedded substrate 1000 in accordance with the present example allows the electronic device 200 to be embedded in the cavity 110 while being supported by the polyimide resin layer 120, thereby allowing the electronic device 200 to be readily embedded in the core substrate 100.

That is, because the polyimide resin layer 120 is used in this example to support the electronic device 200 rather than a heat-resistant tape or the like that needs to be essentially removed, it is possible to prevent a defect in the reliability caused by, for example, a residue of the heat-resistant tape that may remain in the electronic device embedded substrate.

Moreover, because the polyimide resin layer 120 that is used to support the electronic device 200 does not need to be subsequently removed, it is possible to simultaneously carry out a process of forming the insulation layer 300 on both surfaces of the core substrate 100, thereby simplifying the manufacturing process and also minimizing warpage caused by a difference in cure shrinkage of the insulation layers 300 formed on either surface of the core substrate 100.

In the electronic device embedded substrate 1000 in accordance with the present example, the polyimide resin layer 120 may be formed to be relatively thinner than the electronic device 200. That is, the thickness x of the polyimide resin layer 120 formed on one side of the cavity 110 may be limited so as not to cover both surfaces of the electronic device 200.

In the event that the polyimide resin layer 120 is thick enough to completely bury the electronic device 200 under the polyimide resin layer 120, the insulation layer 300 and the polyimide resin layer 120 would be both formed on both surfaces of the core substrate 100, and it may be difficult to carry out, for example, a laser via processing.

Accordingly, in the present example, by forming the electronic device embedded substrate 1000 to be thinner than the electronic device 200, at least one surface of the electronic device 200 may be arranged so as to be exposed or uncovered by the polyimide resin layer 120.

In this example, the polyimide resin layer 120 may be formed with a thickness x of 0.5 to 10 μm. If the polyimide resin layer 120 is too thin, the polyimide resin layer 120 might not provide sufficient adhesiveness for having the electronic device 200 adhered thereto. On the contrary, if the polyimide resin layer 120 is too thick, an overall thickness of the electronic device embedded substrate 1000 would be increased, making it difficult to produce a thinner end product.

Therefore, by forming the polyimide resin layer 120 with the thickness x of 0.5 to 10 μm, the electronic device embedded substrate 1000 in accordance with the present example may provide a sufficient adhesiveness to the electronic device 200 while realizing a thin product.

In the electronic device embedded substrate 1000 in accordance with the present example, the polyimide resin layer 120 may be formed by having a filler impregnated therein. That is, the filler may be included in the polyimide resin layer 120 for structural reinforcement.

Referring to FIG. 1, in the electronic device embedded substrate 1000 in accordance with the present example, the insulation layer 300 has an outer layer circuit pattern 310, which is electrically connected with the electronic device 200, formed therein. However, in another example, the insulation layer 300 may not include an outer layer circuit pattern 310. In this example, the outer layer circuit pattern 310 may be formed through an etching method using photolithography or through an additive method (plating method) and may be connected with the electronic device 200 through a via or the like that penetrates the insulation layer 300. However, the present description shall not be restricted to what is described above, and there may be a variety of modifications if necessary.

Moreover, the outer layer circuit pattern 310 may be made of a metallic material, such as copper (Cu), silver (Ag), gold (Au), aluminum (Al), iron (Fe), titanium (Ti), tin (Sn), nickel (Ni) or molybdenum (Mo).

In the electronic device embedded substrate 1000 in accordance with the present example, an inner layer circuit pattern 130 is formed on a surface of the core substrate 100. Referring to FIG. 1, the inner layer circuit pattern 130 may form an interconnection by being extended and formed on an inner wall surface of the via or the like for electrical connection between both surfaces of the core substrate 100.

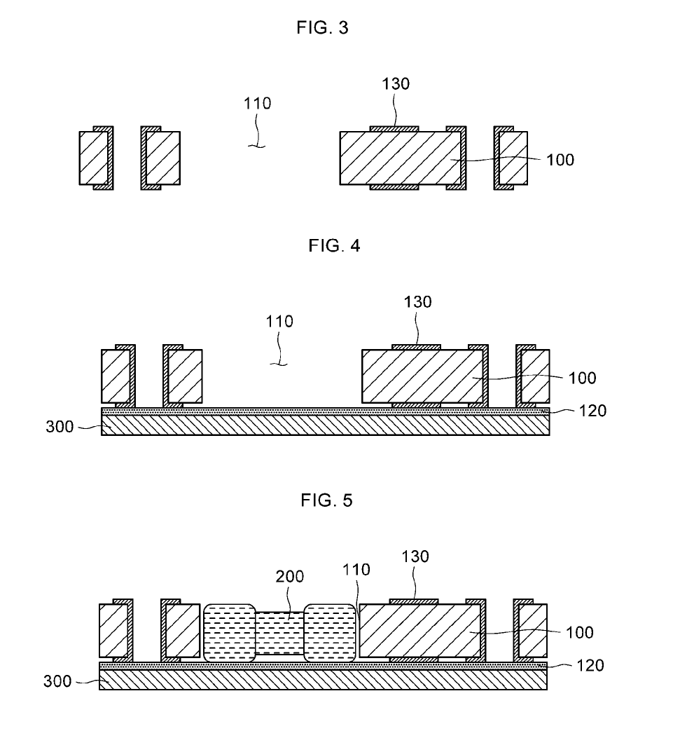

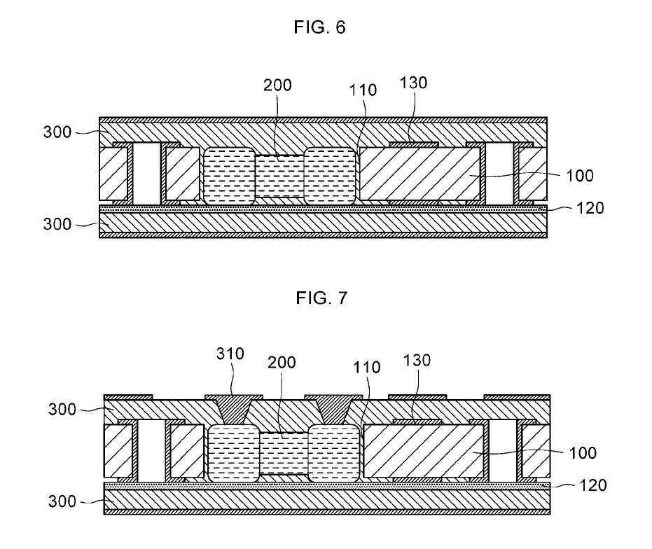

FIG. 2 is a flow diagram showing an example of a method of manufacturing an electronic device embedded substrate. FIG. 3 to FIG. 7 illustrate steps of an example of the method of manufacturing an electronic device embedded substrate.

As illustrated in FIG. 2 to FIG. 7, the method of manufacturing an electronic device embedded substrate in accordance with an embodiment starts with forming a cavity 110 in a core substrate (S100, FIG. 3).

The cavity 110 may be formed by a punching method using a CNC drill or a metallic mold or by a drilling method using laser, such as a CO2 laser or a Nd:YAG laser. The core substrate 100 may have an inner layer circuit pattern 130 formed on a surface thereof, as illustrated in FIG. 3.

Then, as illustrated in FIG. 4, a polyimide resin layer 120 and an insulation layer 300 is formed on one surface of the core substrate 100 so as to cover one side of the cavity 110 (S200). The polyimide resin layer 120 has adhesiveness in a resin state, and thus an electronic device 200 may be adhered thereto. When the polyimide resin layer 120 hardens, the polyimide resin layer 120 may support the electronic device 200 in the cavity 110.

As the polyimide resin layer 120 itself may be used as an insulation material in this example, the polyimide resin layer 120 does not have to be removed after the electronic device 200 is embedded. Moreover, because the polyimide resin layer 120 has a relatively smaller coefficient of thermal expansion than epoxy, compared to a case in which a epoxy layer is used as an insulation material, the polyimide resin layer 120 may form a more stable and sturdy insulation layer.

Next, referring to FIG. 5, the electronic device 200 is embedded in the cavity in such a way that the electronic device is supported by the polyimide resin layer 120 (S300). That is, in this example of the method of manufacturing an electronic device embedded substrate, the electronic device 200 may be supported by use of the polyimide resin layer 120, which does not need to be removed, without using a heat-resistant tape or the like.

Afterwards, referring to FIG. 6, the insulation layer 300 is formed on the other surface of the core substrate 100 so as to cover the core substrate 100 and the electronic device 200 (S400). In this example, the insulation layer 300 is an insulation coated structure configured for protecting the core substrate 100 and the electronic device 200. As illustrated in FIG. 7, an outer layer circuit pattern 310 may be formed in the insulation layer 300 for electrical connection with the electronic device 200.

As described above, because the electronic device 200 is supported by use of the polyimide resin layer 120, which does not need to be removed, instead of the heat-resistant tape or the like that needs to be essentially removed, the method of manufacturing an electronic device embedded substrate in accordance with the present example is capable of preventing a defect in the reliability caused by, for example, a residue of a heat-resistant tape that may remain in the obtained product.

Moreover, because the polyimide resin layer 120 that is used to support the electronic device 200 does not need to be removed, the method of manufacturing an electronic device embedded substrate in accordance with the present example is capable of simultaneously carrying out a process of forming the insulation layer 300 on both surfaces of the core substrate 100, thereby simplifying the manufacturing process and minimizing warpage caused by a difference in cure shrinkage of the insulation layers 300 formed on either surface of the core substrate 100.

In the method of manufacturing an electronic device embedded substrate in accordance with the present example, the S400 step may include compressing a prepreg (PPG) and a copper foil laminated on both surfaces of the core substrate 100.

That is, the insulation layer 300 may be formed by laminating and then compressing the prepreg (PPG) and the copper foil on both surfaces of the core substrate 100. The copper foil may be processed to the outer layer circuit pattern 310 through an etching method using photolithography or through an additive method (plating method).

As a result, the method of manufacturing an electronic device embedded substrate in accordance with the present example allows the insulation layer 300 to be formed readily on both surfaces of the core substrate 100. Since compression may be performed simultaneously on both surfaces of the core substrate 100, the manufacturing process may be further simplified, and a possible warpage caused by a difference in cure shrinkage of the both surfaces of the core substrate 100 may be reduced.

Every element associated with the method of manufacturing an electronic device embedded substrate in accordance with an embodiment has been described in connection with the electronic device embedded substrate 1000 in accordance with an embodiment of and thus will not be redundantly described herein.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic device embedded substrate, comprising:
a core substrate comprising a polyimide resin layer disposed on one side of a cavity of the core substrate;
an electronic device embedded in the cavity; and
an insulation layer disposed on both surfaces of the core substrate so as to cover the core substrate and the electronic device.

2. The electronic device embedded substrate of claim 1, wherein a thickness of the polyimide resin layer is smaller than a thickness of the electronic device.

3. The electronic device embedded substrate of claim 2, wherein the thickness of the polyimide resin layer ranges between approximately 0.5 to 10 μm.

4. The electronic device embedded substrate of claim 1, wherein the polyimide resin layer comprises a resin impregnated with a filler.

5. The electronic device embedded substrate of claim 1, wherein an outer layer circuit pattern is disposed on or within the insulation layer, the outer layer circuit pattern being electrically connected with the electronic device.

6. The electronic device embedded substrate of claim 1, wherein an inner layer circuit pattern is formed on a surface of the core substrate.

7. A method of manufacturing an electronic device embedded substrate, comprising:
forming a cavity in a core substrate;
forming a polyimide resin layer and an insulation layer on one surface of the core substrate so as to cover one side of the cavity;
embedding an electronic device in the cavity by supporting the electronic device with the polyimide resin layer; and
forming an insulation layer on another surface of the core substrate so as to cover the core substrate and the electronic device.

8. The method of claim 7, wherein the forming of the insulation layer comprises compressing a prepreg (PPG) and a copper foil laminated on both surfaces of the core substrate.

9. A method of manufacturing an electronic device embedded substrate, comprising:
disposing an electronic device in a cavity of a core substrate by using a polyimide resin layer; and
embedding the electronic device in the cavity by forming an insulation layer to cover the cavity and the electronic device.

10. The method of claim 9, wherein the embedding of the electronic device comprises forming an insulation layer to cover the electronic device while the electronic device is disposed in the cavity of the core substrate by being supported on the polyimide resin layer.

11. The method of claim 9, further comprising forming an outer layer circuit pattern on or within the insulation layer by forming a via in the insulating layer and filling the via with a conductor such that the outer layer circuit pattern is electrically connected with the electronic device.
